(19) United States
(12) Patent Application Publication
(10) Pub. No.: US 2009/0014317 A1
(43) Pub. Date: Jan. 15, 2009

(54) APPARATUS FOR FILM DEPOSITION ON A CONTINUOUS FLEXIBLE WEB

(75) Inventors: Chia-Yuan CHANG, Taipei Hsien (TW); Chia-Hung Hsu, Hsinchu Hsien (TW)

Correspondence Address: FOLEY AND LARDNER LLP;SUITE 500, 3000 K STREET NW, WASHINGTON, DC, 20007, US

(73) Assignee: INGA NANO TECHNOLOGY CO., LTD.

(21) Appl. No.: 11/926,310

(22) Filed: Oct. 29, 2007

(30) Foreign Application Priority Data
Jul. 12, 2007 (TW) 096125395

(51) Int. Cl. C23C 14/34

(52) U.S. Cl. 204/192.1; 204/298.09; 204/298.15

(57) ABSTRACT

An apparatus for film deposition on a continuous flexible web includes: a deposition chamber; a web-supporting drum disposed rotatably in the deposition chamber and having an outer surface for supporting the flexible web thereon; a web-conveying unit including a web-supplying roller and a web-take-up roller for conveying the continuous flexible web from the web-supplying roller onto the outer surface of the web-supporting drum and then to the web-take-up roller; and a plurality of sputtering guns disposed around the outer surface of the web-supporting drum for depositing a film on the first surface of the flexible web on the outer surface of the web-supporting drum.

### CROSS-REFERENCE TO RELATED APPLICATION

This application claims priority of Taiwanese Application No. 096125395, filed on Jul. 12, 2007.

### BACKGROUND OF THE INVENTION

1. Field of the Invention

This invention relates to an apparatus for film deposition on a continuous flexible web, more particularly to an apparatus including a drum for supporting a continuous flexible web thereon during film deposition.

2. Description of the Related Art

FIG. 1 illustrates a conventional apparatus for film deposition on a continuous flexible web 93. The conventional apparatus includes a supplying roller 92 mounted in a first box 91 and carrying the continuous flexible web 93 thereon, a take-up roller 97 mounted in a second box 98 for storing the flexible web 93, an elongate deposition chamber 94, a plurality of tension-adjusting rollers 99 mounted in the deposition chamber 94, a plurality of upper sputtering guns 95 mounted in the deposition chamber 94, a plurality of lower sputtering guns 95′ mounted in the deposition chamber 94, and a plurality of cooling members 96 mounted in the deposition chamber 94. The continuous flexible web 93 is conveyed by the supplying roller 92 and the take-up roller 97 into the deposition chamber 94 to be deposited with a first film on an upper surface of the flexible web 93 through the upper sputtering guns 95 and a second film on a lower surface of the flexible web 93 through the lower sputtering guns 95′. Since heat is generated in the deposition chamber 94 and is transferred to the flexible web 93 through the deposited material during sputtering, the cooling members 96 are required for cooling the deposition chamber 94 and the flexible web 93 in order to prevent the flexible web 93 from being thermally deformed.

Since the length of the aforesaid conventional apparatus is relatively long, a relatively large space is required to accommodate the same. In addition, since the flexible web 93 is suspended in the deposition chamber 94 and is in free contact with the cooling members 96, the cooling effect on the flexible web 93 is poor.

### SUMMARY OF THE INVENTION

Therefore, the object of the present invention is to provide an apparatus that can overcome the aforesaid drawbacks associated with the prior art.

According to one aspect of this invention, there is provided an apparatus for film deposition on a continuous flexible web having opposite first and second surfaces. The apparatus comprises: a deposition chamber; a web-supporting drum disposed rotatably in the deposition chamber and having an outer surface for supporting the flexible web thereon; a web-conveying unit including a web-supplying roller and a web-take-up roller for conveying the continuous flexible web from the web-supplying roller onto the outer surface of the web-supporting drum and then to the web-take-up roller; and a plurality of sputtering guns disposed around the outer surface of the web-supporting drum for depositing a film on the first surface of the flexible web on the outer surface of the web-supporting drum.

According to another aspect of this invention, there is provided a method for film deposition on a continuous flexible web having opposite first and second surfaces. The method comprises: conveying the continuous flexible web onto an outer surface of a web-supporting drum; disposing a plurality of sputtering guns around the outer surface of the web-supporting drum; and depositing a film on the first surface of the flexible web on the outer surface of the web-supporting drum through the sputtering guns.

### BRIEF DESCRIPTION OF THE DRAWING

Other features and advantages of the present invention will become apparent in the following detailed description of the preferred embodiment of this invention, with reference to the accompanying drawing, in which:

FIG. 1 is a schematic partly sectional view of a conventional apparatus for film deposition on a continuous flexible web; and

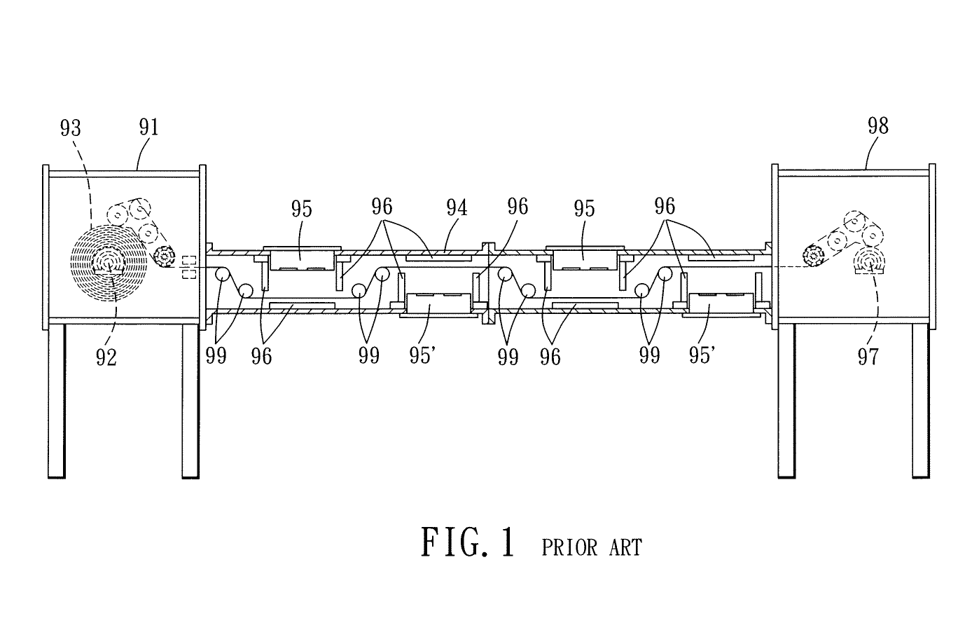

FIG. 2 is a schematic view of the preferred embodiment of an apparatus for film deposition on a continuous flexible web according to this invention.

### DETAILED DESCRIPTION OF THE PREFERRED EMBODIMENT

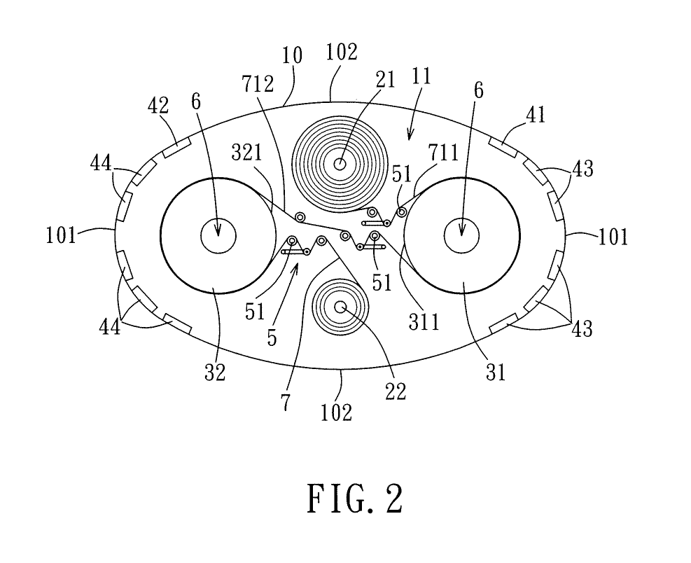

FIG. 2 illustrates the preferred embodiment of an apparatus for film deposition on a continuous flexible web 7 according to this invention. The continuous flexible web 7 has opposite first and second surfaces 711, 712. The apparatus includes: a deposition chamber 11; a first web-supporting drum 31 disposed rotatably in the deposition chamber 11 and having an outer surface 311 for supporting the flexible web 7 thereon; a web-conveying unit 5 including a web-supplying roller 21 and a web-take-up roller 22 for conveying the continuous flexible web 7 from the web-supplying roller 21 onto the outer surface 311 of the first web-supporting drum 31 and then to the web-take-up roller 22; and a plurality of first sputtering guns 43 disposed around the outer surface 311 of the first web-supporting drum 31 for depositing a first film on the first surface 711 of the flexible web 7 on the outer surface 311 of the first web-supporting drum 31.

In this embodiment, the deposition chamber 11 is defined by a peripheral wall 10 having an oval cross-section, two long axial ends 101, and two short axial ends 102. The apparatus further includes a second web-supporting drum 32 disposed rotatably in the deposition chamber 11 and having an outer surface 321 for supporting the flexible web 7 thereon, and a plurality of second sputtering guns 44 disposed around the outer surface 321 of the second web-supporting drum 32 for depositing a second film on the second surface 712 of the flexible web 7 on the outer surface 321 of the second web-supporting drum 32. The first and second web-supporting drums 31, 32 are disposed adjacent to the long axial ends 101 of the peripheral wall 10, respectively.

The first sputtering guns 43 are mounted on one of the long axial ends 101 of the peripheral wall 10, and the second sputtering guns 44 are mounted on the other of the long axial ends 101 of the peripheral wall 10. The web-supplying roller 21 and the web-take-up roller 22 are disposed respectively adjacent to the short axial ends 102 of the peripheral wall 10.

The web-conveying unit 5 is mounted in the deposition chamber 11, and further includes a plurality of tension-adjusting rollers 51 disposed between the first and second web-supporting drums 31, 32 and between the web-supplying roller 21 and the web-take-up roller 22.

The apparatus further includes: first and second cooling members 6 disposed respectively in the first and second web-supporting drums 31, 32 for directly cooling drum walls of the first and second web-supporting drums 31, 32 to thereby cool the flexible web 7 on the outer surfaces 311, 321 of the first and second web-supporting drums 31, 32; and first and second ion guns 41, 42 mounted in the deposition chamber 11. The first ion gun 41 is mounted on said one of the long axial ends 101 of the peripheral wall 10, and is disposed upstream of the first sputtering guns 43 for generating ions to bombard the first surface 711 of the flexible web 7 on the outer surface 311 of the first web-supporting drum 31 so as to roughen and/or clean the first surface 711 of the flexible web 7 prior to film deposition, which can enhance adhesion of the deposited first film to the first surface 711 of the flexible web 7. The second ion gun 42 is mounted on the other of the long axial ends 101 of the peripheral wall 10, and is disposed upstream of the second sputtering guns 44 for generating ions to bombard the second surface 712 of the flexible web 7 on the outer surface 321 of the second web-supporting drum 32 so as to roughen and/or clean the second surface 712 of the flexible web 7 prior to film deposition, which can enhance adhesion of the deposited second film to the second surface 712 of the flexible web 7.

FIG. 2 also illustrates consecutive steps of a method for forming a film on a continuous flexible web 7 according to this invention. The method includes the steps of: conveying the continuous flexible web 7 onto the outer surfaces 311, 321 of the first and second web-supporting drums 31, 32; disposing a plurality of the first sputtering guns 43 around the outer surface 311 of the first web-supporting drum 31 and a plurality of the second sputtering guns 44 around the outer surface 321 of the second web-supporting drum 32; and depositing a first film on the first surface 711 of the flexible web 71 on the outer surface 311 of the first web-supporting drum 31 through the first sputtering guns 43, and a second film on the second surface 712 of the flexible web 7 on the outer surface 321 of the second web-supporting drum 32 through the second sputtering guns 44.

With the inclusion of the first and second web-supporting drums 31, 32 in the apparatus of this invention, the space required for accommodating the apparatus can be considerably reduced as compared to the aforesaid conventional apparatus. In addition, since the outer surfaces 311, 321 of the first and second web-supporting drums 31, 32 are directly cooled by the cooling members 6, the flexible web 7 on the outer surfaces 311, 321 of the first and second web-supporting drums 31, 32 can be cooled more efficiently as compared to that suspended in the deposition chamber of the aforesaid conventional apparatus.

While the present invention has been described in connection with what is considered the most practical and preferred embodiment, it is understood that this invention is not limited to the disclosed embodiment but is intended to cover various arrangements included within the spirit and scope of the broadest interpretation and equivalent arrangements.

What is claimed is:

1. An apparatus for film deposition on a continuous flexible web having opposite first and second surfaces, comprising:
a deposition chamber;
a first web-supporting drum disposed rotatably in said deposition chamber and having an outer surface for supporting the flexible web thereon;
a web-conveying unit including a web-supplying roller and a web-take-up roller for conveying the continuous flexible web from said web-supplying roller onto said outer surface of said first web-supporting drum and then to said web-take-up roller; and
a plurality of first sputtering guns disposed around said outer surface of said first web-supporting drum for depositing a first film on the first surface of the flexible web on said outer surface of said first web-supporting drum.

2. The apparatus of claim 1, wherein said deposition chamber is defined by a peripheral wall having an oval cross-section and two long axial ends, said apparatus further comprising a second web-supporting drum disposed rotatably in said deposition chamber and having an outer surface for supporting the flexible web thereon, and a plurality of second sputtering guns disposed around said outer surface of said second web-supporting drum for depositing a second film on the second surface of the flexible web on said outer surface of said second web-supporting drum, said first and second web-supporting drums being disposed adjacent to said long axial ends of said peripheral wall, respectively.

3. The apparatus of claim 2, wherein said first sputtering guns are mounted on one of said long axial ends of said peripheral wall, and said second sputtering guns are mounted on the other of said long axial ends of said peripheral wall.

4. The apparatus of claim 3, wherein said peripheral wall further has two short axial ends, said web-supplying roller and said web-take-up roller being disposed respectively adjacent to said short axial ends of said peripheral wall.

5. The apparatus of claim 4, wherein said web-conveying unit is mounted in said deposition chamber and further includes a plurality of tension-adjusting rollers disposed between said first and second web-supporting drums and between said web-supplying roller and said web-take-up roller.

6. The apparatus of claim 2, further comprising first and second cooling members disposed respectively in said first and second web-supporting drums for cooling the flexible web on said outer surfaces of said first and second web-supporting drums.

7. The apparatus of claim 1, further comprising an ion gun mounted in said deposition chamber and disposed upstream of said first sputtering guns for generating ions to bombard the flexible web on said outer surface of said first web-supporting drum prior to film deposition.

8. A method for forming a film on a continuous flexible web having opposite first and second surfaces, comprising:
conveying the continuous flexible web onto an outer surface of a first web-supporting drum;
disposing a plurality of first sputtering guns around the outer surface of the first web-supporting drum; and
depositing a first film on the first surface of the flexible web on the outer surface of the first web-supporting drum through the first sputtering guns.

9. The method of claim 8, further comprising conveying the continuous flexible web onto an outer surface of a second web-supporting drum, disposing a plurality of second sputtering guns around the outer surface of the second web-supporting drum, and depositing a second film on the second surface of the flexible web on the outer surface of the second web-supporting drum through the second sputtering guns.
